(19) United States
(12) Patent Application Publication
(10) Pub. No.: US 2008/0160663 A1
(43) Pub. Date: Jul. 3, 2008

(54) METHOD FOR MANUFACTURING OF CMOS IMAGE SENSOR

(75) Inventor: Woo Sung CHO, Ansan-si (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 11/948,796

(22) Filed: Nov. 30, 2007

(30) Foreign Application Priority Data
Dec. 29, 2006 (KR) 10-2006-0137564

(51) Int. Cl. H01L 31/18

(52) U.S. Cl. 438/70; 257/E31.127

(57) ABSTRACT

The present invention relates to a method for manufacturing a CMOS image sensor. The method comprises stacking an interlayer dielectric layer including a plurality of photodiodes on a semiconductor substrate, forming a metal pad on the interlayer dielectric layer, depositing an anti-reflective coating film on the metal pad, depositing a passivation film over the semiconductor substrate and the anti reflective coating film, removing the passivation film on the metal pad, forming a color filter array on the passivation film, removing a portion of the anti-reflective coating film on the metal pad, and forming a planarization layer and a micro lens on the semiconductor substrate and color filter array, wherein when a portion of the metal pad is exposed during the manufacturing process of the CMOS image sensor the anti-reflective coating protects the surface of the metal pad preventing the corrosion of the pad during color filter process.

### CROSS-REFERENCES AND RELATED APPLICATIONS

This application claims the benefit of the Korean Patent Application No. 10-2006-0137564, filed on Dec. 29, 2006, which is hereby incorporated in its entirety.

### BACKGROUND OF THE INVENTION

1. Field of the Invention

The present invention relates to a method of manufacturing a CMOS image sensor. More particularly, the present invention relates to a method for manufacturing a CMOS image sensor capable of preventing the corrosion of a metal pad in a color filtering process.

2. Discussion of the Related Art

During the manufacturing of a general CMOS image sensor, a protective layer is formed to protect the metal wiring. Then, a portion of the protective layer is removed prior to performing a color filtering process.

FIGS. 1A to 1D are cross-sectional views illustrating a method for manufacturing a CMOS image sensor according to the related art. As shown in FIG. 1A, the CMOS image sensor includes a unit pixel part 100 and a portion 105 where an area of a metal pad 150 is exposed. An oxide film 103 and a nitride film 104 as a protective film are formed on the substrate and second metal wiring 101. In some configurations, an anti-reflection layer 102, such as titanium nitride film, is also formed on the second metal wiring 101 at a thickness of about 300 Å. The lower structure the unit pixel structure generally comprises a buried photodiode (BPD), a transfer gate, a reset gate, a driver gate, and a select gate, and the like, according to technology known in the art.

As shown in FIG. 1B, mask and etching processes are performed and a portion 105 of the metal wiring 101 is exposed where the metal wiring may be bonded in a subsequent packaging process. Thus, a portion of the nitride film 104, oxide film 103, and anti-reflection layer 102 are etched to expose a portion 105 of the second metal wiring 101.

Then, a first color filter comprising any one of three primary colors is formed into a pattern on the upper surface of the buried photodiode, forming the light-sensing of the unit pixel.

However, as shown in FIG. 1C, a dyed photoresistor comprising a red color filter material 106 is coated on the upper surface of the of the nitride film 104 and second metal wiring 101. Then, the a red color filter material 106b burying the exposed portion 105 of the metal wiring is removed, leaving only a red color filter material 106a over the photodiode area. Then, a thermal treatment process is performed in order to siliconize the red color filter 106a. Generally, the process is performed at a temperature between 145 and 150° C. A similar process is used in order to form blue and green color filters.

One difference between the red color filter, blue color filter, and green color filter is the number of times that they are dipped into a developer. That is, the process of forming a blue color filter has a development time that is three times longer than the process for forming a green color filter, and is seven times longer than the process for forming a red color filter. Accordingly, the time that the exposed metal surface is oxidized (corroded) is related to the amount of time that the exposed metal is exposed to the developer. Thus, the oxidation of the exposed metal gradually increases depending on the color of the photoresistors. Thus, as shown in FIG. 1D, the exposed metal surface 107 is covered with an oxide 108 with high resistance to protect the exposed metal 107, but which impedes contact between the exposed metal surface 107 and a metal ball during a subsequent packaging process.

Recent experiments have determined that devices formed using the color filter forming process have twice the electrode resistance than existed in the devices prior to forming the color filter. Further, analysis of the pad metal surface shows devices formed with the color filter forming process have been exposed to more oxygen and have an three times the infiltration depth of the oxygen than existed prior to the color filter forming process. Thus the photoresist reacts with melting oxygen in the developer when the metal is exposed in the color filter forming process.

Another disadvantage of the present manufacturing process is a residue often remains after developing the color filter material. In some instances, the residue is removed by a plasma method, which causes the crystal structure of the exposed metal surface to weaken and may increase the degree of oxidation of the metal.

Additionally, the oxide film 108 formed on the metal surface generates an aluminum oxide when the metal used is aluminum. Unfortunately, the aluminum oxide is very difficult to remove. That is, the etching selectivity of plasma large enough that, the aluminum oxide may remain, making the electrical contact with the metal unstable when packaging.

### BRIEF SUMMARY OF THE INVENTION

The present invention proposes to solve these and other problems of the current art. It is an object of the present invention to provide a method for manufacturing a CMOS image sensor wherein metal corrosion due to the color filter process is prevented

In order to accomplish these objects, one aspect of the present invention is a method comprising forming an interlayer dielectric layer including a plurality of photodiodes on a semiconductor substrate, forming a metal pad on the interlayer dielectric layer, depositing an anti-reflective coating film on the metal pad, sequentially depositing a passivation oxide film and a passivation nitride film over the semiconductor substrate and anti-reflective film, removing the passivation oxide film and the passivation nitride film on the metal pad, forming a color filter array on the passivation nitride film, removing the anti-reflective coating film on the metal pad, forming a planarization layer and a micro lens on the semiconductor substrate and color filter array.

### BRIEF DESCRIPTION OF THE DRAWING

The accompanying drawings are included to provide a further understanding of the invention and are incorporated in and constitute a part of this application. The drawings illustrate embodiment(s) of the invention and together with the description serve to explain the principle of the invention. In the drawings:

FIGS. 1A to 1D are cross-sectional views showing a method for manufacturing a CMOS image sensor known in the related art; and,

FIGS. 2A to 2D are cross-sectional views showing a method for manufacturing a CMOS image sensor according to one embodiment of the present invention.

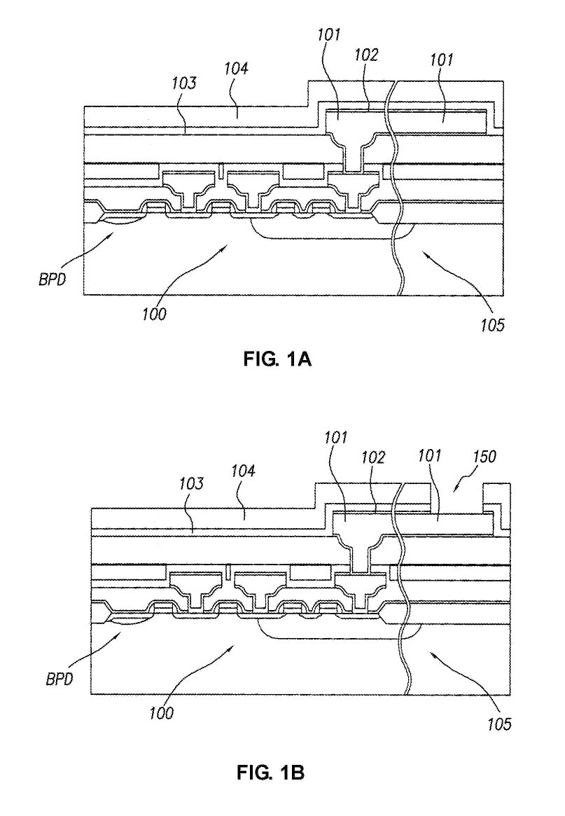

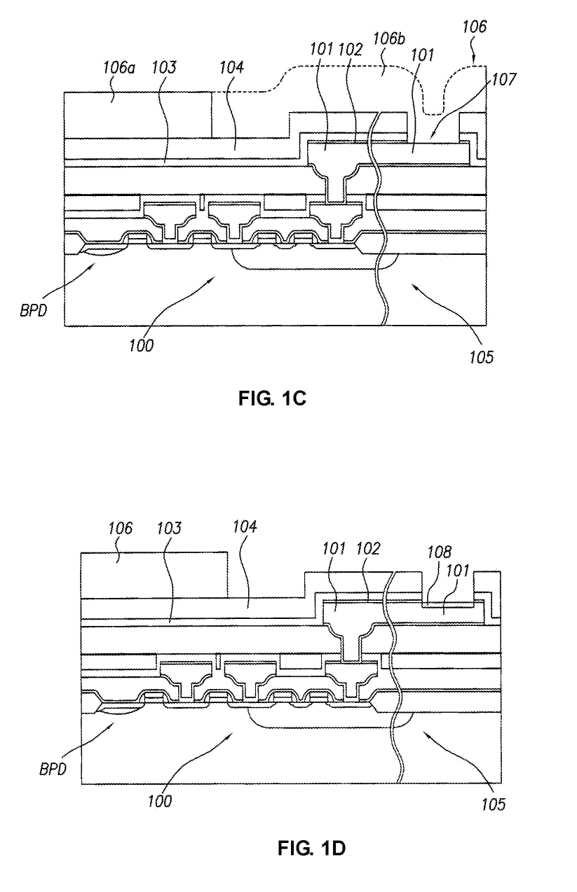

### DETAILED DESCRIPTION OF THE INVENTION

Hereinafter, the preferred embodiment of the present invention will be described with reference to the accompanying drawings. In this description, detailed descriptions of well-known techniques are omitted so as not to obscure the description of the present invention with unnecessary detail.

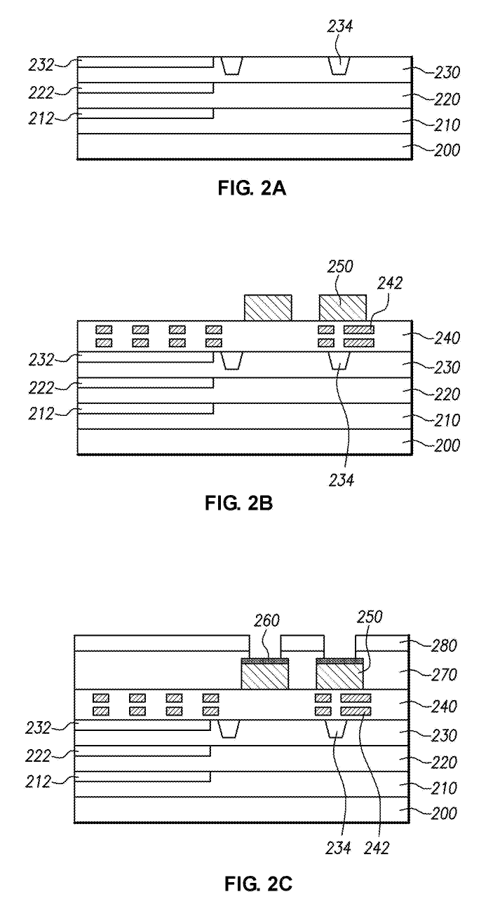

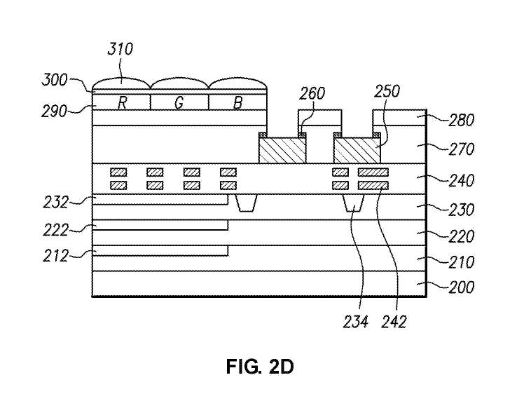

FIGS. 2A to 2D are cross-sectional views showing a method for manufacturing a CMOS image sensor according to one embodiment of the present invention.

As shown in FIG. 2A, a red photodiode 212 is formed on a semiconductor substrate 200 on which a first epitaxial 210 layer is grown. Then, a second epitaxial layer 220 is grown on the semiconductor substrate 200 and red photodiode 212. Then, a green photodiode 222 is formed on the second epitaxial layer 220.

Next, a third epitaxial layer 230 is grown on the second epitaxial layer 220 and green photodiode 222. Then, a blue photodiode device 232 and a trench insulating area are formed on the third epitaxial layer 230, and the trench is filled with an insulating material in order to form a shallow trench isolation 234.

Then, as shown in FIG. 2B, an interlayer dielectric layer 240 is stacked on the third epitaxial layer 230 and a first metal layer (not shown) is formed and into a pattern on the interlayer dielectric layer 240 so as to form a metal wiring 242.

The interlayer dielectric layer 240 and metal wiring 242 processes are repeated several times in order to form the necessary metal wiring 242. Finally, a second metal layer (not shown) is deposited and formed into a pattern on the stacked interlayer dielectric layer 240 so as to form a metal pad 250.

As shown in FIG. 2C, an anti-reflective coating film 260 such as titanium nitride film (TiN) is deposited on the metal pad 250. Then, in this example, passivation films, including a passivation oxide film 270 and a passivation nitride film 280, are sequentially deposited over the semiconductor substrate 200 and anti-reflective coating film 260 in order to protect the device from moisture or physical impact.

Then, a dry etching process having etching selectivity is performed on the passivation oxide film 270 and passivation nitride film 280. The passivation oxide film 270 and passivation nitride film 280 are removed from the surface of the anti-reflective coating film 260 using a dry etching process. Accordingly, the anti-reflective coating film 260 remains with a very thin thickness on the metal pad 250.

As shown in FIG. 2D, a dyed photoresist is coated on the passivation nitride film 280. The photodiode is formed on the surface of the dyed photoresist and is formed into a pattern by means of an exposure and development process so as to form red, green, and blue color filter arrays 290. Then, the anti-reflective coating film 260 on the metal pad 242 is removed using a dry etching process. Because the anti-reflective coating 260 is very thin, the breakage of the color filter arrays 290 is minimized so that the color filter arrays 290 are able to maintain their original shape. Specially, when the metal pad is exposed, the anti reflective coating 260 is not entirely removed in order to prevent the corrosion of the exposed portion of the metal pad during the color filtering process. That is, an anti reflective coating 260 with very thin thickness remains.

Next, a planarization layer 300 is formed on the semiconductor substrate 200 including the color filter arrays 290 and a micro lens 310 is formed on the planarization layer 300.

Although the preferable embodiments of the present invention have been described above, the present invention can be implemented in modified forms without departing from the essential scope or meaning of the present invention by those skilled in the art.

Therefore, the embodiment of the present invention described herein should be considered as illustrative only, rather than as limiting. The scope of the present invention is shown in the claims, rather than the above description, and all differences present within equivalents should be construed as included in the present invention.

Within the present invention as described above, when a portion of the metal pad is exposed in the manufacturing process of the CMOS image sensor, an anti-reflective coating film with very thin thickness is left on the surface of the metal pad so that the corrosion of the color filter process can be prevented.

Consequently, the present invention improves the yield and reliability of the semiconductor device.

What is claimed is:

1. A method for manufacturing a CMOS image sensor comprising:
forming an interlayer dielectric layer including a plurality of photodiodes on a semiconductor substrate;
forming a metal pad on the interlayer dielectric layer;
depositing an anti reflective coating film on the metal pad;
depositing a passivation film over the semiconductor substrate and anti-reflective coating film;
removing a portion of the passivation film from the metal pad;
forming a color filter array on the passivation film;
removing a portion of the anti-reflective coating film from the metal pad; and
forming a planarization layer and a micro lens on the semiconductor substrate and color filter array.

2. The method according to claim 1, wherein the anti reflective coating film is formed of titanium nitride (TiN).

3. The method according to claim 1, wherein a portion of the passivation oxide film and passivation nitride are removed from the metal pad using a dry etching process having etching selectivity for the passivation oxide film and passivation nitride film.

4. The method according to claim 1, wherein a portion of the anti reflective coating film is removed from the metal pad using a dry etching process.

5. The method according to claim 1, further comprising forming a metal wiring in the interlayer dielectric layer.

6. The method according to claim 1, wherein the interlayer dielectric includes metal wiring.

7. The method according to claim 1, wherein a portion of anti-reflective coating film is removed, while a thin layer of the anti reflective coating film remains on the metal pad.

8. A method for manufacturing a CMOS image sensor comprising:
forming an interlayer dielectric layer including a plurality of photodiodes on a semiconductor substrate;
forming a metal pad on the interlayer dielectric layer;
depositing an anti reflective coating film on the metal pad;
depositing a passivation film over the semiconductor substrate and anti-reflective coating film;
removing a portion of the passivation film from the metal pad;
forming a color filter array on the passivation film;
removing a portion of the anti-reflective coating film from the metal pad using a dry etching process; and
forming a planarization layer and a micro lens on the semiconductor substrate and color filter array;
wherein a portion of the passivation oxide film and passivation nitride are removed from the metal pad using a dry etching process having etching selectivity for the passivation oxide film and passivation nitride film.

9. The method according to claim 8, wherein the anti reflective coating film is formed of titanium nitride (TiN).

10. The method according to claim 8, further comprising forming a metal wiring in the interlayer dielectric layer.

10. The method according to claim 8, wherein the interlayer dielectric includes metal wiring.

11. The method according to claim 8, wherein a portion of anti-reflective coating film is removed, while a thin layer of the anti reflective coating film remains on the metal pad.
